(19) United States
(12) Patent Application Publication
(10) Pub. No.: US 2021/0138512 A1
(43) Pub. Date: May 13, 2021

(54) SUBSTRATE PROCESSING METHOD AND SUBSTRATE PROCESSING APPARATUS

(71) Applicant: SCREEN Holdings Co., Ltd., Kyoto (JP)

(72) Inventors: Hiroaki TAKAHASHI, Kyoto (JP); Yuya AKANISHI, Kyoto (JP)

(21) Appl. No.: 17/047,415

(22) PCT Filed: Apr. 9, 2019
(86) PCT No.: PCT/JP2019/015446

§ 371 Date: Oct. 14, 2020

(30) Foreign Application Priority Data
Apr. 20, 2018 (JP) 2018-081326

(51) Int. Cl. B08B 3/08; H01L 21/02; H01L 21/67; B08B 3/10; B08B 3/04

(52) U.S. Cl. CPC B08B 3/08; H01L 21/02068; B08B 2203/002; B08B 3/10; B08B 3/041; H01L 21/67051

(57) ABSTRACT

A substrate processing method includes generating a low-oxygen processing liquid by reducing oxygen dissolved in a processing liquid (step S12), and processing a main surface (i.e., upper surface) of a substrate by supplying the low-oxygen processing liquid to the substrate, the upper surface having a first metal part and a second metal part in contact with the first metal part (step S14). In the step S14, the low-oxygen processing liquid is brought into contact with an interface between the first metal part and the second metal part to inhibit oxygen reduction reaction on the second metal part which is nobler than the first metal part, and thereby to inhibit dissolution of the first metal part. According to the substrate processing method, it is possible to suitably inhibit dissolution of the metal part (i.e., the first metal part) on the substrate.

### TECHNICAL FIELD

The present invention relates to a technique for processing a substrate.

### BACKGROUND ART

Conventionally, in manufacturing semiconductor substrates (hereinafter, referred to simply as “substrates”), various types of processing are performed on the substrate using a substrate processing apparatus. For example, in a substrate processing apparatus of Japanese Patent Application Laid-Open No. 2015-173285 (Document 1), chemical liquid processing is performed on a substrate having a metal pattern exposed on a surface by supplying a chemical liquid such as dilute hydrofluoric acid having a reduced oxygen concentration. In the chemical liquid processing, use of the chemical liquid having a reduced oxygen concentration inhibits oxidation of the metal pattern.

On the other hand, when an interface between dissimilar metals is exposed on a surface of a substrate, the phenomenon in which the baser metal is dissolved by the potential difference between the dissimilar metals (so-called galvanic corrosion) may occur. Thus, Japanese Patent Application Laid-Open No. 2004-172576 (Document 2) has proposed a technique where, when an etching is performed on a substrate having a surface on which an interface between a copper (Cu) wiring pattern and a metal layer is exposed, a protective film is formed on the surface of the copper wiring pattern by adding benzotriazole (BTA) or the like to an etching liquid, to inhibit dissolution of the copper wiring pattern.

Japanese Patent Application Laid-Open No. 2004-128109 (Document 3) has proposed a technique where, by adjusting percentages of tungsten (W) and nitrogen (N) constituting a metal layer which is in contact with a copper wiring pattern on a substrate, dissolution of the copper wiring pattern is inhibited. Japanese Patent Application Laid-Open No. 2008-91875 (Document 4) has proposed a technique where a dissolution prevention film is sandwiched between an aluminum (Al) wiring pattern and a barrier metal layer on a substrate in order to inhibit dissolution of the aluminum wiring pattern.

In the technique of Document 2, because the protective film on the surface of the copper wiring pattern remains after cleaning the substrate, wiring resistance may increase. In the technique of Document 3, because the percentage of nitrogen in the metal layer increases, wiring resistance may increase. In Document 4, the cross-sectional area of the aluminum wiring pattern decreases because of the insertion of the dissolution prevention film, and thus wiring resistance may increase.

### SUMMARY OF INVENTION

The present invention is intended for a substrate processing method, and it is an object of the present invention to suitably inhibit dissolution of a metal part on a substrate.

The substrate processing method according to a preferred embodiment of the present invention includes a) generating a low-oxygen processing liquid by reducing oxygen dissolved in a processing liquid, and b) processing a main surface of a substrate by supplying the low-oxygen processing liquid to the substrate, the main surface having a first metal part and a second metal part in contact with the first metal part. In the operation b), the low-oxygen processing liquid is brought into contact with an interface between the first metal part and the second metal part to inhibit oxygen reduction reaction on the second metal part which is nobler than the first metal part, and thereby to inhibit dissolution of the first metal part. According to the present invention, it is possible to suitably inhibit dissolution of a metal part on a substrate.

Preferably, in the operation a), bubbles of a gas other than oxygen are supplied into the processing liquid to reduce oxygen in the processing liquid.

Preferably, in the operation a), the processing liquid is run through a pipe made of an oxygen permeable material while a space outside the pipe is set to a low-oxygen atmosphere, to reduce oxygen in the processing liquid.

Preferably, a dissolved oxygen concentration of the low-oxygen processing liquid is equal to or less than 500 ppb.

Preferably, the substrate processing method further includes c) setting a target value of dissolved oxygen concentration of the low-oxygen processing liquid before the operation a). In generation of the low-oxygen processing liquid in the operation a), the dissolved oxygen concentration of the low-oxygen processing liquid is controlled to be equal to or less than the target value.

Preferably, in the operation c), the target value of dissolved oxygen concentration is set on the basis of a combination of the first metal part and the second metal part.

Preferably, in the operation b), the dissolved oxygen concentration of the low-oxygen processing liquid when supplied to the substrate is equal to or less than the target value.

Preferably, the substrate processing method further includes d) supplying an inert gas into a space on the main surface of the substrate to reduce an oxygen concentration in a surrounding atmosphere, in parallel with the operation b).

Preferably, in the operation d), the inert gas is injected toward a space in a vicinity of an outer edge portion of the substrate.

Preferably, the low-oxygen processing liquid supplied to the substrate in the operation b) is a cleaning chemical liquid used for cleaning the main surface of the substrate. The substrate processing method further includes e) rinsing the main surface of the substrate by supplying a rinsing liquid to the main surface after the operation b). In the operation b), the low-oxygen processing liquid is supplied to the main surface of the substrate rotating at a first rotation speed. In the operation e), the rinsing liquid is supplied to the main surface of the substrate rotating at a second rotation speed which is higher than the first rotation speed.

Preferably, the first metal part is included in a wiring part provided on the main surface of the substrate.

Preferably, the processing in the operation b) is performed as a cleaning process for removing from the main surface of the substrate process residue generated in a pre-process performed before the operation b).

The present invention is also intended for a substrate processing apparatus. The substrate processing apparatus according to a preferred embodiment of the present invention includes an oxygen reduction part for generating a low-oxygen processing liquid by reducing oxygen dissolved in a processing liquid, and a liquid supply part for supplying the low-oxygen processing liquid to a substrate whose main surface has a first metal part and a second metal part in contact with the first metal part. The low-oxygen processing liquid is brought into contact with an interface between the first metal part and the second metal part to inhibit oxygen reduction reaction on the second metal part which is nobler than the first metal part, and thereby to inhibit dissolution of the first metal part. According to the present invention, it is possible to suitably inhibit dissolution of a metal part on a substrate.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view of a substrate processing apparatus according to an embodiment;

FIG. 2 is a cross-sectional view of the substrate processing apparatus;

FIG. 3 is a block diagram of a gas-liquid supply part;

FIG. 4 is a view of an example of an oxygen reduction part;

FIG. 5 is a view of another example of an oxygen reduction part;

FIG. 6 is a diagram of a configuration of a controller;

FIG. 7 is a flowchart of an example of processing a substrate;

FIG. 8 is a vertical cross-sectional view showing a vicinity of an upper surface of a substrate;

FIG. 9 is a schematic view showing a state in which a processing liquid that is not deoxidized is in contact with an interface between dissimilar metals;

FIG. 10 is a side view of a dissimilar metal structure;

FIG. 11 is an illustration of experimental results;

FIG. 12 is an illustration of experimental results;

FIG. 13 is an illustration of experimental results;

FIG. 14 is an illustration of experimental results;

FIG. 15 is an illustration of experimental results;

FIG. 16 is an illustration of experimental results.

### DESCRIPTION OF EMBODIMENTS

FIG. 1 is a cross-sectional view of a substrate processing apparatus 1 according to an embodiment of the present invention. The substrate processing apparatus 1 is a single wafer processing apparatus for processing generally disk-like semiconductor substrates 9 (hereinafter, simply referred to as “substrates 9”) one at a time by supplying a processing liquid. In the present embodiment, residue generated in a pre-process (the residue is, for example, polymer residue generated in a dry etching process or an ashing process, and is hereinafter referred to as “pre-process residue”) adheres to the substrate 9, and the substrate processing apparatus 1 performs a cleaning process by supplying a cleaning chemical liquid to the substrate 9 to remove the pre-process residue from the substrate 9. In FIG. 1, hatching is omitted from cross sections of some constituents in the substrate processing apparatus 1 (the same applies to the other cross-sectional views).

The substrate processing apparatus 1 includes a chamber 11, a substrate holder 31, a substrate rotation mechanism 33, a cup part 4, a top plate 5, a top plate moving mechanism 6, a center nozzle 73, and a controller 8. The controller 8 controls constituent elements of the substrate processing apparatus 1.

For example, the substrate holder 31, the substrate rotation mechanism 33, the cup part 4, the top plate 5, the top plate moving mechanism 6 and the like are housed in the internal space 10 of the chamber 11. The side wall part of the chamber 11 is provided with a conveyance port 12 through which the substrate 9 is conveyed into the internal space 10 of the chamber 11 and the substrate 9 is conveyed out from the internal space 10. While the conveyance port 12 is closed, the internal space 10 of the chamber 11 is a hermetically-closed space. The canopy part of the chamber 11 is provided with a fan unit 13 for feeding a gas toward the internal space 10 of the chamber 11. The gas fed downward from the fan unit 13 is discharged out of the chamber 11 through the bottom part of the chamber 11. As a result, a downward gas flow (so-called downflow) is formed in the chamber 11.

The substrate holder 31 is a chuck that holds the substrate 9 in a horizontal position. The substrate 9 is located above the substrate holder 31. The substrate holder 31 is, for example, a generally disk-like member about a central axis J1 pointing in the up-down direction. The substrate rotation mechanism 33 rotates the substrate 9 together with the substrate holder 31 about the central axis J1. The substrate rotation mechanism 33 is located below the substrate holder 31 and is housed inside a boss part 34 having a generally cylindrical shape with a top cover. In other words, the boss part 34 is a substrate rotation mechanism housing part that houses the substrate rotation mechanism 33. The substrate rotation mechanism 33 is, for example, an electric motor that has a rotating shaft extending in the up-down direction with its center lying on the central axis J1.

The top plate 5 is a generally disk-like member located above the substrate holder 31 and the substrate 9. The top plate 5 is a facing-member that faces the upper main surface 91 (hereinafter, referred to as the “upper surface 91”) of substrate 9 in the up-down direction. In the state shown in FIG. 1, the top plate 5 is suspended and supported by the top plate moving mechanism 6. The diameter of the top plate 5 is greater than that of the substrate 9. The outer peripheral edge of the top plate 5 is located outside the outer peripheral edge of the substrate 9 in a radial direction about the central axis J1 (hereinafter, simply referred to as the “radial direction”) along the entire circumference thereof.

The top plate 5 includes a plate canopy part 51, a plate side wall part 52, a plate cylindrical part 53, and a plate flange part 54. The plate canopy part 51 is a generally circular ring plate-like portion about the central axis J1. The plate canopy part 51 has a generally circular opening 50 about the central axis J1, in the central portion thereof. The plate canopy part 51 is located above the substrate 9 and faces the upper surface 91 of the substrate 9 in the up-down direction. A plurality of side nozzles 73a are provided in a portion of the plate canopy part 51 which faces the peripheral edge portion of the substrate 9 in the up-down direction, and the plurality of side nozzles 73a are arranged in a circumferential direction about the central axis J1 (hereinafter, simply referred to as the “circumferential direction”).

The plate side wall part 52 is a generally cylindrical portion that extends downward from the outer edge portion of the plate canopy part 51. The plate side wall part 52 is located outside the outer peripheral edge of the substrate 9 and the outer peripheral edge of the upper surface of the substrate holder 31 in the radial direction. The plate cylindrical part 53 is a generally cylindrical portion that extends upward from the peripheral edge portion of the opening 50 of the plate canopy part 51. The plate flange part 54 is a generally circular ring plate-like portion that extends outward in the radial direction from the upper end portion of the plate cylindrical part 53.

On the lower surface of the outer circumferential portion of the plate canopy part 51, a plurality of first engagement parts 55 are arranged in the circumferential direction. The plurality of first engagement parts 55 are located inside the plate side wall part 52 in the radial direction. The lower portion of each first engagement part 55 is provided with a recess that is recessed upward. On the upper surface of the outer circumferential portion of the substrate holder 31, a plurality of second engagement parts 35 are arranged in the circumferential direction. The plurality of second engagement parts 35 are located outside the substrate 9 in the radial direction. Each second engagement part 35 protrudes upward from the substrate holder 31 and faces the first engagement part 55 in the up-down direction.

The top plate moving mechanism 6 includes a support canopy part 61, a support cylindrical part 62, a support flange part 63, a support arm 64, and an elevating mechanism 65. The support canopy part 61 is a generally circular ring plate-like portion about the central axis J1. The support canopy part 61 is located above the plate flange part 54 and faces the plate flange part 54 in the up-down direction. The support canopy part 61 has a generally circular opening about the central axis J1, in the central portion thereof. The center nozzle 73 is fixed to the opening. The center nozzle 73 is a generally columnar member that extends downward from the support canopy part 61. In the state shown in FIG. 1, the lower portion of the center nozzle 73 is inserted into the plate cylindrical part 53 of the top plate 5.

The support cylindrical part 62 is a generally cylindrical portion that extends downward from the outer edge portion of the support canopy part 61. The support cylindrical part 62 is located outside the outer peripheral edge of the plate flange part 54 in the radial direction. The support flange part 63 is a generally circular ring plate-like portion that extends inward in the radial direction from the lower end portion of the support cylindrical part 62. The support flange part 63 is located below the plate flange part 54 and faces the plate flange part 54 in the up-down direction. The inner edge of the support flange part 63 is located inside the outer peripheral edge of the plate flange part 54 in the radial direction and located outside the plate cylindrical part 53 in the radial direction. In the state shown in FIG. 1, the upper surface of the support flange part 63 is in contact with the lower surface of the plate flange part 54, and thus the top plate 5 is supported by the top plate moving mechanism 6.

The support arm 64 is a generally rod-like member that extends in a nearly horizontal direction from the side surface of the support canopy part 61. The outer end portion of the support arm 64 in the radial direction is connected to the elevating mechanism 65. The elevating mechanism 65 is an elevator for moving the support arm 64 in the up-down direction. The support arm 64 is moved in the up-down direction by the elevating mechanism 65, and the top plate 5 is moved in the up-down direction together with the support canopy part 61, the support cylindrical part 62, and the support flange part 63. The elevating mechanism 65 is, for example, a linear motor driving in the up-down direction.

The cup part 4 is a generally ring-like member about the central axis J1. The cup part 4 is located around the entire circumferences of the substrate 9 and the substrate holder 31. The cup part 4 includes a first cup 41 and a second cup 42. The first cup 41 is located outside the second cup 42 in the radial direction and above the second cup 42. The inner peripheral edge of the first cup 41 approximately coincides with the inner peripheral edge of the second cup 42 in a plan view. The first cup 41 and the second cup 42 can move in the up-down direction independently of each other by a cup moving mechanism (not shown).

When the top plate 5 is moved down from the position shown in FIG. 1 to the position shown in FIG. 2 by the top plate moving mechanism 6, the second engagement parts 35 of the substrate holder 31 are inserted into the first engagement parts 55 of the top plate 5 from the underside, and the top plate 5 is supported by the substrate holder 31. The top plate 5 and the substrate holder 31 are engaged with each other in a state in which they cannot move relative to each other in the circumferential direction by engagement of the first engagement parts 55 with the second engagement parts 35.

In the state shown in FIG. 2, the plate canopy part 51 of the top plate 5 is close to the upper surface 91 of the substrate 9, and the volume of the generally columnar space 90 between the plate canopy part 51 and the substrate 9 (hereinafter, referred to as “processing space 90”) is smaller than that shown in FIG. 1. The lower end portion of the plate side wall part 52 is close to the outer peripheral edge of the upper surface of the substrate holder 31. Thus, the processing space 90 is isolated to some extent from the space surrounding the processing space 90 in the internal space 10 of the chamber 11. The processing space 90 is not a closed space completely isolated from the surrounding space because there is a gap between the plate side wall part 52 and the substrate holder 31 through which the processing liquid described later can pass.

In the state shown in FIG. 2, the plate flange part 54 of the top plate 5 is separated upward from the support flange part 63 of the top plate moving mechanism 6, and the top plate 5 and the top plate moving mechanism 6 are not in contact with each other. In other words, the holding of the top plate 5 by the top plate moving mechanism 6 is released. In the state shown in FIG. 2, the top plate 5 can be rotated by the substrate rotation mechanism 33 together with the substrate holder 31 and the substrate 9 held by the substrate holder 31, independently of the top plate moving mechanism 6.

In the substrate processing apparatus 1, a liquid (for example, a low-oxygen processing liquid or a rinsing liquid described later) is supplied from the center nozzle 73 inserted into the plate cylindrical part 53 while the substrate holder 31, the substrate 9, and the top plate 5 are rotated by the substrate rotation mechanism 33. The liquid supplied from the center nozzle 73 to the central portion of the upper surface 91 of the substrate 9 moves outward in the radial direction by centrifugal force, and scatters outward in the radial direction from the outer peripheral edge of the substrate 9. The liquid scattered from the substrate 9 is scattered from the gap between the top plate 5 and the substrate holder 31 to the surroundings, and is received by the cup part 4. The liquid received by the cup part 4 is discharged to the outside of the chamber 11 through a discharge port (not shown). In the substrate processing apparatus 1, the center nozzle 73 and the plurality of side nozzles 73a supply an inert gas to the processing space 90. Thus, the processing space 90 is set to an inert gas atmosphere.

FIG. 3 is a block diagram of a gas-liquid supply part 7 included in the substrate processing apparatus 1. In FIG. 3, some constituents other than the gas-liquid supply part 7 are also shown. The gas-liquid supply part 7 includes a liquid supply part 71, a gas supply part 72, and an oxygen reduction part 77. The liquid supply part 71 supplies a liquid to the substrate 9. The liquid supply part 71 includes the aforementioned center nozzle 73, pipes 741, 751, and valves 742, 752.

The pipe 741 of the liquid supply part 71 connects the center nozzle 73 to the oxygen reduction part 77. The valve 742 is provided in the pipe 741. The oxygen reduction part 77 is connected to a processing liquid supply source 701. The oxygen reduction part 77 reduces oxygen (02) dissolved in a processing liquid supplied from the processing liquid supply source 701, and feeds the processing liquid into the pipe 741. In the following description, the processing liquid fed from the oxygen reduction part 77 is referred to as “low-oxygen processing liquid.” In other words, the oxygen reduction part 77 generates the low-oxygen processing liquid by reducing oxygen dissolved in the processing liquid. The pipe 741 is provided with a dissolved oxygen concentration sensor 731 for measuring a dissolved oxygen concentration of the low-oxygen processing liquid flowing through the pipe 741. The dissolved oxygen concentration sensor 731 is preferably provided in the vicinity of the center nozzle 73. The value measured by the dissolved oxygen concentration sensor 731 is sent to the controller 8.

The structure of the oxygen reduction part 77 is not particularly limited as long as it can generate a low-oxygen processing liquid from the processing liquid. For example, the oxygen reduction part 77 may be a bubbling apparatus 77a shown in FIG. 4. The bubbling apparatus 77a includes a storage tank 771, a bubble supply part 772, a pipe 774, and a valve 775. The inside of the storage tank 771 is shown in FIG. 4.

The storage tank 771 stores the processing liquid 770 supplied from the aforementioned processing liquid supply source 701. The storage tank 771 is, for example, a generally rectangular parallelepiped container. The space inside the storage tank 771 is a hermetically-closed space. An exhaust valve 776 is provided on the upper portion of the storage tank 771, and the pressure in the space inside the storage tank 771 is adjusted by the exhaust valve 776.

The bubble supply part 772 is a generally tubular member located near the bottom portion in the storage tank 771. The bubble supply part 772 has a plurality of bubble supply ports 773. The bubble supply part 772 is connected to an additive gas supply source 704 via the pipe 774. The valve 775 is provided in the pipe 774. The additive gas fed from the additive gas supply source 704 is led to the bubble supply part 772 via the pipe 774 and the valve 775, and the additive gas is supplied as bubbles into the processing liquid 770 in the storage tank 771 from the plurality of bubble supply ports 773 of the bubble supply part 772. The valve 775 regulates the flow rate of the additive gas flowing through the pipe 774.

The additive gas is a type of gas different from oxygen. As the additive gas, an inert gas is preferably used. When the same type of gas as an inert gas supplied from an inert gas supply source 703 described later is used as the additive gas, the inert gas supply source 703 may also be used as the additive gas supply source 704.

In the bubbling apparatus 77a, deoxidization of the processing liquid 770 is performed by supplying bubbles of the additive gas into the processing liquid 770 from the bubble supply part 772, and the dissolved oxygen concentration of the processing liquid 770 is lowered. The processing liquid 770 whose dissolved oxygen concentration is reduced (i.e., the low-oxygen processing liquid) is fed from the storage tank 771 to the center nozzle 73 (see FIG. 3) via the aforementioned pipe 741 and valve 742. The bubbling apparatus 77a adjusts the dissolved oxygen concentration of the low-oxygen processing liquid fed from the bubbling apparatus 77a to the center nozzle 73, by adjusting the amount of bubbles of the additive gas supplied to the processing liquid 770 using the valve 775. Further, the pressure in the storage tank 771 is adjusted by the exhaust valve 776 to adjust the dissolved oxygen concentration of the low-oxygen processing liquid fed from the bubbling apparatus 77a to the center nozzle 73.

The oxygen reduction part 77 may be, for example, the degassing module 77b shown in FIG. 5. The degassing module 77b includes a closed container 777, a permeable pipe 778, and an exhaust valve 779. The closed container 777 is a container having a closed space inside. The permeable pipe 778 is located in the internal space of the closed container 777. Both ends of the permeable pipe 778 are connected to the outside of the closed container 777. The permeable pipe 778 has a flow path through which a liquid flows. The outer wall of the permeable pipe 778 is made of material that is permeable to oxygen and impermeable to any liquid. The exhaust valve 779 is provided in a pipe connecting a suction mechanism (not shown) and the closed container 777.

In the degassing module 77b, the internal space of the closed container 777 is depressurized by opening the exhaust valve 779 while the suction mechanism is driven. In this state, the processing liquid supplied from the aforementioned processing liquid supply source 701 passes through the permeation pipe 778, so that oxygen in the processing liquid permeates the outer wall of the permeation pipe 778 to the outside of the permeation pipe 778. In other words, the processing liquid flowing through the permeation pipe 778 is deoxidized, and the dissolved oxygen concentration of the processing liquid is reduced. The processing liquid having a reduced dissolved oxygen concentration (i.e., the low-oxygen processing liquid) is fed from the permeation pipe 778 to the center nozzle 73 (see FIG. 3) via the aforementioned pipe 741 and valve 742. The degassing module 77b adjusts the dissolved oxygen concentration of the low-oxygen processing liquid fed from the degassing module 77b to the center nozzle 73, by adjusting the pressure in the closed container using the exhaust valve 779.

Further, in the degassing module 77b, instead of depressurizing the internal space of the closed container 777, by filling the internal space with an inert gas such as nitrogen (N₂) gas or argon (Ar) gas, the processing liquid flowing through the permeation pipe 778 can be deoxidized. That is, in the degassing module 77b, the processing liquid can be deoxidized by setting the internal space of the closed container 777 to a low-oxygen atmosphere (for example, an atmosphere having an oxygen percentage of 0.0005% by volume or less).

In the present embodiment, the processing liquid supplied from the processing liquid supply source 701 shown in FIG. 3 to the oxygen reduction part 77 is a chemical liquid for a cleaning process (that is, a cleaning chemical liquid). The chemical liquid is, for example, dilute hydrofluoric acid (DHF), hydrochloric acid, acetic acid, citric acid, glycolic acid, SC2, aqueous ammonia, SC1 or the like. The processing liquid may be a liquid other than the chemical liquid for the cleaning process. The low-oxygen processing liquid (in the present embodiment, the low-oxygen cleaning chemical liquid) fed from the oxygen reduction part 77 is led to the center nozzle 73 via the pipe 741 and the valve 742, and supplied from the center nozzle 73 to the central portion of the upper surface 91 of the substrate 9. The valve 742 regulates the flow rate of the low-oxygen processing liquid flowing through the pipe 741.

The pipe 751 of the liquid supply part 71 connects the center nozzle 73 and the rinsing liquid supply source 702. The valve 752 is provided in the pipe 751. The rinsing liquid fed from the rinsing liquid supply source 702 is led to the center nozzle 73 via the pipe 751 and the valve 752, and is supplied from the center nozzle 73 to the central portion of the upper surface 91 of the substrate 9. The valve 752 regulates the flow rate of the rinsing liquid flowing through the pipe 751. The rinsing liquid is, for example, pure water (DIW: De-Ionized Water) or the like. The rinsing liquid may be a liquid other than pure water.

The gas supply part 72 supplies an inert gas to the processing space 90. The gas supply part 72 includes the aforementioned center nozzle 73, the plurality of side nozzles 73a, a pipe 761, and a valve 762. In other words, the center nozzle 73 is shared by the liquid supply part 71 and the gas supply part 72. The pipe 761 of the gas supply part 72 connects the center nozzle 73 and the plurality of side nozzles 73a to the inert gas supply source 703. The valve 762 is provided in the pipe 761.

The inert gas fed from the inert gas supply source 703 is led to the center nozzle 73 and the plurality of side nozzles 73a via the pipe 761 and the valve 762, and is supplied to the processing space 90 from the center nozzle 73 and the plurality of side nozzles 73a. The valve 762 regulates the flow rate of the inert gas flowing through the pipe 761. The inert gas is, for example, nitrogen gas or the like. The inert gas may be a gas other than nitrogen gas (for example, argon gas).

In the substrate processing apparatus 1, the aforementioned controller 8 controls the valve 742 of the liquid supply part 71 to adjust the flow rate of the low-oxygen processing liquid supplied from the center nozzle 73 to the substrate 9. The controller 8 controls the valve 752 of the liquid supply part 71 to adjust the flow rate of the rinsing liquid supplied from the center nozzle 73 to the substrate 9. Further, the controller 8 controls the valve 762 of the gas supply part 72 to adjust the flow rate of the inert gas supplied from the center nozzle 73 and the plurality of side nozzles 73a to the processing space 90.

In the substrate processing apparatus 1, the controller 8 controls the oxygen reduction part 77 to adjust the dissolved oxygen concentration of the low-oxygen processing liquid generated by the oxygen reduction part 77. For example, when the bubbling apparatus 77a shown in FIG. 4 is used as the oxygen reduction part 77, the controller 8 controls the valve 775 and/or the exhaust valve 776 to adjust the dissolved oxygen concentration of the low-oxygen processing liquid. When the degassing module 77b shown in FIG. 5 is used as the oxygen reduction part 77, the controller 8 controls the exhaust valve 779 to adjust the dissolved oxygen concentration of the low-oxygen processing liquid.

As the controller 8, for example, a normal computer is used. FIG. 6 is a diagram of a configuration of the controller 8. The controller 8 includes a processor 81, a memory 82, an input/output part 83, and a bus 84. The bus 84 is a signal circuit that connects the processor 81, the memory 82, and the input/output part 83. The memory 82 is a storage part that stores programs and various information. The processor 81 executes various processes (for example, numerical calculation and image processing) according to a program and the like stored in the memory 82 while using the memory 82 and the like. The input/output part 83 includes a keyboard 85 and a mouse 86 that receive input from the operator, and a display 87 that displays the output from the processor 81 and the like.

FIG. 7 is a flowchart of an example of processing the substrate 9 by the substrate processing apparatus 1. In the substrate processing apparatus 1, first, a target value is set for the dissolved oxygen concentration of the aforementioned low-oxygen processing liquid and stored in the controller 8 (step S11). The target value is preferably set on the basis of the combination of a first metal part 93 and a second metal part 94 described later on the substrate 9. The target value is set, for example, by an operator's input via the input/output part 83 of the controller 8. Alternatively, there may be a case where a table or the like showing a relationship between the combination of the first metal part 93 and the second metal part 94 and the aforementioned target value is stored in advance in the controller 8, information indicating the actual combination is input into the controller 8 by the operator, and therefore the target value is automatically set in the controller 8. The target value is, for example, 500 ppb.

Subsequently, the oxygen reduction part 77 reduces the dissolved oxygen concentration of the processing liquid to generate a low-oxygen processing liquid (step S12). In step S12, the controller 8 controls the oxygen reduction part 77, so that the dissolved oxygen concentration of the low-oxygen processing liquid is controlled to be equal to or less than the aforementioned target value. Preferably, the dissolved oxygen concentration of the low-oxygen processing liquid is controlled so as to be approximately equal to the target value. The dissolved oxygen concentration of the low-oxygen processing liquid generated in step S12 is, for example, equal to or less than 500 ppb.

For example, when the bubbling apparatus 77a shown in FIG. 4 is used as the oxygen reduction part 77, the controller 8 controls the valve 775, the exhaust valve 776 or the like, so that the dissolved oxygen concentration of the low-oxygen processing liquid is controlled. When the degassing module 77b shown in FIG. 5 is used as the oxygen reduction part 77, the controller 8 controls the exhaust valve 779 or the like, so that the dissolved oxygen concentration of the low-oxygen processing liquid is controlled.

Then, the top plate 5 is moved down from the position shown in FIG. 1 to the position shown in FIG. 2 by the top plate moving mechanism 6. The top plate 5 is separated from the top plate moving mechanism 6 and is supported by the substrate holder 31. The substrate 9, the substrate holder 31, and the top plate 5 are rotated at a predetermined rotation speed (hereinafter, referred to as “first rotation speed”) by the substrate rotation mechanism 33.

After the rotation of the substrate 9 is started, the controller 8 controls the gas supply part 72 (for example, the valve 762 or the like), so that the inert gas fed from the inert gas supply source 703 is fed from the center nozzle 73 and the plurality of side nozzles 73a. Specifically, the inert gas is supplied from the center nozzle 73 to the space on the central portion of the substrate 9, and the inert gas is supplied from the plurality of side nozzles 73a to the space in the vicinity of the outer edge portion of the substrate 9. As a result, the inert gas is supplied to the space on the entire upper surface 91 of the substrate 9 (i.e., the processing space 90), and the oxygen concentration in the atmosphere of the processing space 90 is reduced (step S13). In other words, the processing space 90 is set to a low-oxygen atmosphere.

After the processing space 90 becomes the low-oxygen atmosphere, the controller 8 controls the liquid supply part 71 (for example, the valve 742 or the like), so that the low-oxygen processing liquid fed from the oxygen reduction part 77 is supplied from the center nozzle 73 to the central portion of the upper surface 91 of the substrate 9 rotating at the first rotation speed (for example, 200 rpm to 800 rpm). The low-oxygen processing liquid supplied on the substrate 9 moves outward in the radial direction by centrifugal force, scatters from the outer peripheral edge of the substrate 9 to the surroundings, and is received by the cup part 4. In the substrate processing apparatus 1, processing is performed on the upper surface 91 of the substrate 9 by continuing to supply the low-oxygen processing liquid to the substrate 9 for a predetermined time (step S14).

In the present embodiment, as described above, the processing in step S14 is performed as a cleaning process for removing from the upper surface 91 of the substrate 9 the pre-process residue which is process residue generated in a pre-process performed before step S14 (for example, a dry etching process or an ashing process performed before conveyance of the substrate 9 into the substrate processing apparatus 1).

In the substrate processing apparatus 1, while step S14 is being performed, the supply of the inert gas from the center nozzle 73 and the plurality of side nozzles 73a to the processing space 90 is continued. In other words, step S13 is continuously performed in parallel with step S14. Thus, the processing space 90 is maintained in the low-oxygen atmosphere during step S14.

Further, in the substrate processing apparatus 1, while step S14 is being performed, the dissolved oxygen concentration of the low-oxygen processing liquid flowing through the pipe 741 (i.e., the low-oxygen processing liquid immediately before discharge from the center nozzle 73) is measured by the dissolved oxygen concentration sensor 731. The measurement by the dissolved oxygen concentration sensor 731 may be performed continuously or intermittently. When the value measured by the dissolved oxygen concentration sensor 731 is greater than a predetermined threshold value, for example, the controller 8 displays a warning on the display 87 and emits an alarm sound. The threshold value may be, for example, the same as the aforementioned target value set in step S11, or may be a value slightly less than the target value. As a result, in step S14, the dissolved oxygen concentration of the low-oxygen processing liquid at the time of supply to the substrate 9 becomes equal to or less than the aforementioned target value. Specifically, the dissolved oxygen concentration of the low-oxygen processing liquid when supplied to the substrate 9 is preferably equal to or less than 500 ppb, and more preferably equal to or less than 70 ppb.

When the processing of the substrate 9 with the low-oxygen processing liquid is completed, the supply of the low-oxygen processing liquid from the center nozzle 73 is stopped. Then, the rotation speed of the substrate 9 by the substrate rotation mechanism 33 is increased to a second rotation speed (for example, 500 rpm to 1200 rpm) higher than the first rotation speed. Subsequently, the controller 8 controls the liquid supply part 71 (for example, the valve 752 or the like), so that the rinsing liquid fed from the rinsing liquid supply source 702 is supplied from the center nozzle 73 to the central portion of the upper surface 91 of the substrate 9 rotating at the second rotation speed. The rinsing liquid supplied onto the substrate 9 moves outward in the radial direction by centrifugal force, scatters from the outer peripheral edge of the substrate 9 to the periphery, and is received by the cup part 4. In the substrate processing apparatus 1, the upper surface 91 of the substrate 9 is rinsed by continuing to supply the rinsing liquid to the substrate 9 for a predetermined time (step S15). In the substrate processing apparatus 1, the inert gas is continuously supplied to the processing space 90 in parallel with step S15, and the processing space 90 is maintained in the low-oxygen atmosphere.

When the rinsing process of the substrate 9 is completed, the supply of the rinsing liquid from the center nozzle 73 is stopped. Further, the rotation speed of the substrate 9 by the substrate rotation mechanism 33 is further increased to a third rotation speed (for example, 1500 rpm to 2500 rpm) higher than the second rotation speed. Thus, the rinsing liquid on the substrate 9 is scattered from the outer peripheral edge of the substrate 9 and removed from the substrate 9. In the substrate processing apparatus 1, the substrate 9 is dried by continuing the removal of the rinsing liquid by the high-speed rotation of the substrate 9 for a predetermined time (step S16). In the substrate processing apparatus 1, the inert gas is continuously supplied to the processing space 90 in parallel with step S16, and the processing space 90 is maintained in the low-oxygen atmosphere. In the substrate processing apparatus 1, the drying process of step S16 may be performed after a replacing liquid such as IPA (isopropyl alcohol) is supplied onto the upper surface 91 of the substrate 9 to replace the rinsing liquid on the substrate 9 with the replacing liquid between steps S15 and S16.

FIG. 8 is a vertical cross-sectional view showing the vicinity of the upper surface 91 of the substrate 9. The substrate 9 includes a first metal part 93 and a second metal part 94. The first metal part 93 and the second metal part 94 are included in a wiring part 96 (i.e., a wiring pattern) formed in an insulating film 952 provided on the silicon substrate 951. The second metal part 94 is the main body of the wiring part 96 (i.e., wiring main body). The first metal part 93 is a metal film (for example, a liner film) that is located between the second metal part 94 and the insulating film 952 and covers the side surface and the bottom surface of the second metal part 94. An anti-diffusion film 953 made of, for example, tantalum nitride (TaN) is provided between the second metal part 94 and the insulating film 952. The first metal part 93 and the second metal part 94 are in direct contact with each other. The upper end surface of the first metal part 93 and the upper end surface of the second metal part 94 are exposed on the upper surface 91 of the substrate 9. The interface between the first metal part 93 and the second metal part 94 is also exposed on the upper surface 91 of the substrate 9.

The second metal part 94 is made of a noble metal having a higher standard electrode potential than the first metal part 93. In other words, the first metal part 93 is made of a metal that is baser than the second metal part 94. The combination of the first metal part 93 and the second metal part 94 is, for example, cobalt (Co) and copper (Cu), copper and ruthenium (Ru), titanium (Ti) and cobalt, or the like. Each of the first metal part 93 and the second metal part 94 is not limited to a single metal, and may be an alloy. The names of the first metal part 93 and the second metal part 94 are determined by the high-low relation of the standard electrode potentials regardless of the shape and structure of the metal parts. Thus, the wiring main body of the wiring part 96 may be the first metal part 93, and the metal film such as the liner film may be the second metal part 94.

When the interface between dissimilar metals is exposed in this way, galvanic corrosion (i.e., contact corrosion between dissimilar metals) occurs by the processing liquid which is not deoxidized and which adheres to the interface, and the base metal whose standard electrode potential is relatively low is dissolved. As a comparative example, FIG. 9 is an enlarged schematic view showing a state in which the processing liquid 20 that is not deoxidized is in contact with the interface 23 between the base metal 21 and the noble metal 22. In this case, on the surface of the noble metal 22, the oxygen reduction reaction of Formula 1 or Formula 2 occurs by using oxygen in the processing liquid 20 and electrons in the noble metal 22. Further, as shown in Formula 3, metal is dissolved as ions into the processing liquid 20 from the surface of the base metal 21, and electrons are supplied to the noble metal 22. In Formula 3 and FIG. 9, the base metal is represented as “M” for convenience.

O₂+4H⁺+e⁻→2H₂O (1)

O₂+2H₂O+4e⁻→4OH⁻ (2)

M→M^{x+}+x e⁻ (3)

On the other hand, in the processing of the substrate 9 in the substrate processing apparatus 1 shown in FIG. 1, the liquid supplied to the upper surface 91 of the substrate 9 is the low-oxygen processing liquid having a reduced dissolved oxygen concentration, and it is therefore possible to inhibit the aforementioned oxygen reduction reaction on the surface of the second metal part 94 made of the noble metal. As a result, the dissolution of the first metal part 93 made of the base metal can be inhibited.

As described above, the aforementioned substrate processing method includes the step (step S12) of generating a low-oxygen processing liquid by reducing oxygen dissolved in a processing liquid, and the step (step S14) of processing a main surface (i.e., upper surface 91) of a substrate 9 by supplying the low-oxygen processing liquid to the substrate 9, the upper surface 91 having a first metal part 93 and a second metal part 94 in contact with the first metal part 93. In step S14, the low-oxygen processing liquid is brought into contact with an interface between the first metal part 93 and the second metal part 94 to inhibit oxygen reduction reaction on the second metal part 94 which is nobler than the first metal part 93, and thereby to inhibit dissolution of the first metal part 93. According to the substrate processing method, it is possible to suitably inhibit dissolution of the metal part (i.e., the first metal part 93) on the substrate 9 due to galvanic corrosion.

In the substrate 9, if the metal part included in the wiring part 96 is dissolved, the performance of the substrate 9 is greatly and adversely affected. Therefore, the aforementioned substrate processing method capable of suitably inhibiting the dissolution of the first metal part 93 is particularly suitable for the processing of the substrate 9 whose upper surface 91 has the wiring part 96 including the first metal part 93. Further, the substrate processing method capable of suitably inhibiting the dissolution of the first metal part 93 is particularly suitable for a case where the processing in step S14 is performed as not a process such as etching of the first metal part 93 but a cleaning process for removing from the upper surface 91 of the substrate 9 process residue which is generated in the pre-process performed before step S14.

In the substrate processing method, it is preferable that bubbles of a gas other than oxygen are supplied into the processing liquid to reduce oxygen in the processing liquid in step S12. This makes it possible to easily reduce the dissolved oxygen concentration of the processing liquid. For example, the processing liquid can be easily deoxidized by using the bubbling apparatus 77a shown in FIG. 4.

In the substrate processing method, it is also preferable that the processing liquid is run through a pipe (i.e., the permeable pipe 778) made of an oxygen permeable material while a space outside the pipe is set to a low-oxygen atmosphere, to reduce oxygen in the processing liquid in step S12. This makes it possible to easily reduce the dissolved oxygen concentration of the processing liquid. For example, the processing liquid can be easily deoxidized by using the degassing module 77b shown in FIG. 5.

Preferably, the aforementioned substrate processing method further includes the step (step S11) of setting a target value of dissolved oxygen concentration of the low-oxygen processing liquid before step S12. In generation of the low-oxygen processing liquid in step S12, the dissolved oxygen concentration of the low-oxygen processing liquid is controlled to be equal to or less than the target value. By adjusting the dissolved oxygen concentration of the low-oxygen processing liquid to an appropriate concentration, it is possible to more suitably inhibit dissolution of the first metal part 93 due to galvanic corrosion.

More preferably, the dissolved oxygen concentration of the low-oxygen processing liquid is controlled so as to be equal to the target value. This makes it possible to prevent the dissolved oxygen concentration of the low-oxygen processing liquid from being reduced more than necessary. As a result, the time and cost required to generate the low-oxygen processing liquid can be reduced, and the processing efficiency of the substrate 9 can be improved.

In the substrate processing method, it is preferable that the target value of dissolved oxygen concentration is set on the basis of a combination of the first metal part 93 and the second metal part 94 in step S11. Therefore, even when the types of metals forming the first metal part 93 and the second metal part 94 are changed, dissolution of the first metal part 93 due to galvanic corrosion can be suitably inhibited. In addition, it is possible to prevent the dissolved oxygen concentration of the low-oxygen processing liquid from being reduced more than necessary, and to reduce the time and cost required to generate the low-oxygen processing liquid.

In step S14, it is preferable that the dissolved oxygen concentration of the low-oxygen processing liquid when supplied to the substrate 9 is equal to or less than the above target value. This makes it possible to more suitably inhibit dissolution of the first metal part 93 due to galvanic corrosion.

It is preferable that the substrate processing method further includes the step (step S13) of supplying an inert gas into the space on the upper surface 91 of the substrate 9 (i.e., the processing space 90) to reduce an oxygen concentration in the surrounding atmosphere, in parallel with step S14. It is therefore possible to inhibit increase of the dissolved oxygen concentration of the low-oxygen processing liquid which is caused by dissolution of oxygen in the surrounding atmosphere into the low-oxygen processing liquid supplied on the substrate 9. As a result, dissolution of the first metal part 93 due to galvanic corrosion can be more suitably inhibited. In this case, the oxygen concentration in the processing space 90 is preferably equal to or less than 1000 ppm, more preferably equal to or less than 250 ppm.

The thickness of the low-oxygen processing liquid on the substrate 9 (i.e., the film thickness) becomes thinner as the low-oxygen processing liquid moves from the central portion to the outer edge portion of the substrate 9 by centrifugal force. As above, when the film thickness of the low-oxygen processing liquid becomes thin, if oxygen in the surrounding atmosphere dissolves into the low-oxygen processing liquid through the surface thereof, the oxygen easily reaches the second metal part 94, and the possibility of galvanic corrosion of the first metal part 93 increases. Additionally, as compared with the central portion of the substrate 9, at the outer edge portion of the substrate 9, the film surface of the low-oxygen processing liquid on the substrate 9 is more likely to be disturbed by the influence of centrifugal force or the like and to involve the surrounding atmosphere, and there is a relatively high possibility that oxygen will dissolve into the low-oxygen processing liquid. Further, since the low-oxygen processing liquid on the outer edge portion of the substrate 9 has a longer elapsed time after the discharge from the center nozzle 73 than the low-oxygen processing liquid on the central portion of the substrate 9, the amount of oxygen dissolved in the low-oxygen processing liquid on the outer edge portion is relatively large.

Thus, in the aforementioned substrate processing method, it is more preferable that the inert gas is injected toward a space in the vicinity of the outer edge portion of the substrate 9 in step S13. Therefore, dissolution of the first metal part 93 due to galvanic corrosion can be suitably inhibited at the outer edge portion of the substrate 9 where galvanic corrosion is more likely to occur than at the central portion of the substrate 9.

Preferably, the low-oxygen processing liquid supplied to the substrate 9 in step S14 is a cleaning chemical liquid used for cleaning the upper surface 91 of the substrate 9. The aforementioned substrate processing method further includes the step (step S15) of rinsing the upper surface 91 of the substrate 9 by supplying a rinsing liquid to the upper surface 91 after step S14. In step S14, the low-oxygen processing liquid is supplied to the upper surface 91 of the substrate 9 rotating at a first rotation speed. In step S15, the rinsing liquid is supplied to the upper surface 91 of the substrate 9 rotating at a second rotation speed which is higher than the first rotation speed.

As above, in process of step S14 in which galvanic corrosion is more likely to occur than the rinsing process of step S15, the rotation speed of the substrate 9 is lowered so that the film thickness of the low-oxygen processing liquid on the substrate 9 is relatively thickened. Thus, even if oxygen in the surrounding atmosphere is dissolved into the low-oxygen processing liquid, the oxygen is inhibited from reaching the second metal part 94, and dissolution of the first metal part 93 due to galvanic corrosion can be inhibited.

As described above, the substrate processing apparatus 1 includes the oxygen reduction part 77 and the liquid supply part 71. The oxygen reduction part 77 generates a low-oxygen processing liquid by reducing oxygen dissolved in a processing liquid. The liquid supply part 71 supplies the low-oxygen processing liquid to the substrate 9 whose main surface (i.e., the upper surface 91) has a first metal part 93 and a second metal part 94 in contact with the first metal part 93. In the substrate processing apparatus 1, the low-oxygen processing liquid is brought into contact with an interface between the first metal part 93 and the second metal part 94 to inhibit oxygen reduction reaction on the second metal part 94 which is nobler than the first metal part 93, and thereby to inhibit dissolution of the first metal part 93. According to the substrate processing apparatus 1, it is possible to suitably inhibit dissolution of the metal part (i.e., the first metal part 93) on the substrate 9 due to galvanic corrosion.

In the following description, experiments for verifying the effect of inhibiting galvanic corrosion by the aforementioned substrate processing method will be described. FIG. 10 is a side view of a dissimilar metal structure 981 used in a first experiment. The dissimilar metal structure 981 includes a metal bump 982 and a base metal 983. The metal bump 982 is a generally columnar member with a diameter of about 8 μm and a height of about 5 μm. The lower surface of the metal bump 982 is joined to the base metal 983 while being in direct contact with the base metal 983. The metal bump 982 is made of cobalt, and the base metal 983 is made of copper. That is, the metal bump 982 corresponds to the first metal part 93, which is a baser metal. The base metal 983 corresponds to the second metal part 94, which is a nobler metal.

FIG. 11 shows states of the dissimilar metal structures 981 after immersion in dilute hydrofluoric acid having dissolved oxygen concentrations of 70 ppb, 500 ppb, 1200 ppb, and 3000 ppb, respectively. The upper part of FIG. 11 shows the states after a lapse of 300 seconds from the start of the immersion (that is, the case where the processing time is 300 seconds), and the lower part shows the states after a lapse of 600 seconds from the start of the immersion (that is, the case where the processing time is 600 seconds). The concentration of dilute hydrofluoric acid is 0.05%, and the temperature of dilute hydrofluoric acid is room temperature (for example, about 15° C.). The experimental atmosphere is an air atmosphere.

As shown in FIG. 11, in the case where the dissolved oxygen concentration of dilute hydrofluoric acid is 3000 ppb, the metal bump 982 is largely dissolved after 300 seconds of processing, and the metal bump 982 is almost completely dissolved and has disappeared after 600 seconds of processing. In the metal bump 982 after 300 seconds of processing, the amount of dissolution (i.e., the thickness lost by dissolution) at the lower end in contact with the base metal 983 is greater than the amount of dissolution at the upper end, and thus it can be seen that the main cause of dissolution of the metal bump 982 is galvanic corrosion that occurs in the vicinity of the interface between the dissimilar metals. In the case where the dissolved oxygen concentration of dilute hydrofluoric acid is 1200 ppb, the lower end of the metal bump 982 is largely dissolved by galvanic corrosion after 600 seconds of processing.

On the other hand, in the case where the dissolved oxygen concentration of dilute hydrofluoric acid is 500 ppb, the metal bump 982 is hardly dissolved after 300 seconds of processing and after 600 seconds of processing. Further, the amount of dissolution at the lower end of the metal bump 982 (that is, the vicinity of the interface with the base metal 983) is substantially equal to or slightly greater than the amount of dissolution on the side surface and the upper surface of the metal bump 982 (so-called loss amount of a bulk layer). The same is true in the case where the dissolved oxygen concentration of dilute hydrofluoric acid is 70 ppb. From this, it can be seen that in the case where the dissolved oxygen concentration of dilute hydrofluoric acid is equal to or less than 500 ppb, galvanic corrosion of the metal bump 982 hardly occurs.

FIG. 12 is an illustration of second experimental results. In the second experiment, substrates 984 in each of which a plurality of wiring parts 96 shown in FIG. 8 are arranged in the transverse direction are used. As above, each wiring part 96 includes a first metal part 93 made of cobalt, and a second metal part 94 made of copper. The substrates 984 are processed by supplying dilute hydrofluoric acid having dissolved oxygen concentrations of 70 ppb, 500 ppb and 3000 ppb in the substrate processing apparatus 1. The upper part of FIG. 12 shows vertical cross-sectional views of the substrates 984, and the lower part shows perspective views of the upper surfaces of the substrates 984. The supply time of dilute hydrofluoric acid to the substrate 984 is 180 seconds. The concentration of dilute hydrofluoric acid is 0.05%, and the temperature of dilute hydrofluoric acid is room temperature (for example, about 15° C.). The experimental atmosphere is an air atmosphere.

FIG. 13 shows the result of analysis by EDS elemental mapping analysis for one wiring part 96 after supply of dilute hydrofluoric acid having a dissolved oxygen concentration of 3000 ppb. FIG. 14 shows the result of analysis by EDS elemental mapping analysis for one wiring part 96 after supply of dilute hydrofluoric acid having a dissolved oxygen concentration of 70 ppb.

As shown in FIGS. 12 to 14, in the case where the dissolved oxygen concentration of dilute hydrofluoric acid is 3000 ppb, the first metal part 93 is dissolved by galvanic corrosion, and a gap 93a is formed around the second metal part 94. On the other hand, in the case where the dissolved oxygen concentration of dilute hydrofluoric acid is 500 ppb or 70 ppb, the first metal part 93 is hardly dissolved. From this, it can be seen that when the dissolved oxygen concentration of dilute hydrofluoric acid is equal to or less than 500 ppb, galvanic corrosion of the first metal part 93 hardly occurs.

According to the experimental results shown in FIGS. 11 to 14, in the aforementioned substrate processing method, the dissolved oxygen concentration of the low-oxygen processing liquid is preferably equal to or less than 500 ppb. This makes it possible to more suitably inhibit dissolution of the first metal part 93 due to galvanic corrosion. More preferably, the dissolved oxygen concentration of the low-oxygen processing liquid is equal to or less than 70 ppb. This makes it possible to yet more suitably inhibit dissolution of the first metal part 93 due to galvanic corrosion.

FIG. 15 is an illustration showing difference in dissolution of the wiring parts 96 due to positions on the substrate 984 in the experiment shown in FIG. 12. The upper part of FIG. 15 shows the experimental result in the case where the experimental atmosphere is an air atmosphere, and the lower part shows the experimental result in the case where the experimental atmosphere is a nitrogen atmosphere. FIG. 15 shows the degree of dissolution of the wiring parts 96, in the substrate 984 having a diameter of 300 mm, at the center of the substrate, the intermediate position (position 55 mm outward in the radial direction from the center of the substrate), and the outer edge portion (position 110 mm outward in the radial direction from the center of the substrate). The dissolved oxygen concentration of dilute hydrofluoric acid is 70 ppb. The supply time of dilute hydrofluoric acid to the substrate 984 is 180 seconds. The concentration of dilute hydrofluoric acid is 0.05%, and the temperature of dilute hydrofluoric acid is room temperature (for example, about 15° C.).

As shown in FIG. 15, in the case where the experimental atmosphere is an air atmosphere, the first metal part 93 is slightly dissolved at the outer edge portion of the substrate 9, and the first metal part 93 is hardly dissolved at the center and the intermediate positions of the substrate 9. In the case where the experimental atmosphere is a nitrogen atmosphere, the first metal part 93 is hardly dissolved at the center, the intermediate position and the outer edge portion of the substrate 9. From this, in order to inhibit galvanic corrosion of the first metal part 93, it can be seen that it is preferable to reduce the oxygen concentration of the atmosphere by supplying the inert gas into the space on the upper surface 91 of the substrate 9 in parallel with step S14, as above. Further, at this time, it can be seen that it is more preferable that the inert gas is injected toward the space in the vicinity of the outer edge portion of the substrate 9.

FIG. 16 is an illustration showing the measurement results of the in-plane distribution of etching rate, for verification of the relationship between the rotation speed of the substrate 9 and the dissolution of the first metal part 93. In the substrate having a diameter of 300 mm, the distance in the radial direction between the measurement position and the center of the substrate is indicated as r (mm) on the horizontal axis. The vertical axis shows the etching rate (nm/min) of cobalt at each measurement position. The etching rate increases as the dissolved oxygen concentration of the etching liquid increases. Thus, it is considered that if the etching rate can be reduced, the dissolution of the first metal part 93 due to galvanic corrosion can be inhibited.

At each measurement position in FIG. 16, the left bar shows the etching rate in the case where the rotation speed of the substrate is 1200 rpm, and the right bar shows the etching rate in the case where the rotation speed of the substrate is 200 rpm. Dilute hydrofluoric acid is used as the etching liquid. The concentration of dilute hydrofluoric acid is 0.05%, and the temperature of dilute hydrofluoric acid is room temperature (for example, about 15° C.). The experimental atmosphere is an air atmosphere.

As shown in FIG. 16, in the case where the rotation speed of the substrate is 1200 rpm, the etching rate increases as it approaches the outer edge portion of the substrate. On the other hand, in the case where the rotation speed of the substrate is 200 rpm, there is not much difference in the etching rate depending on the measurement position. It is considered that this is because the film thickness of dilute hydrofluoric acid on the substrate becomes thinner by increasing the rotation speed of the substrate, and the influence on the etching rate of oxygen dissolved in the dilute hydrofluoric acid from the surrounding atmosphere becomes larger. In particular, as above, oxygen is likely to be dissolved at the outer edge portion of the substrate, and the film thickness at the outer edge portion is thinner than those at the center and the like of the substrate. Therefore, it is thought that the influence on the etching rate of oxygen dissolved in the dilute hydrofluoric acid from the surrounding atmosphere becomes yet larger at the outer edge portion.

From this, in order to inhibit galvanic corrosion of the first metal part 93, as above, it can be seen that it is preferable to reduce the oxygen concentration in the surrounding atmosphere by supplying the inert gas into the space on the upper surface 91 of the substrate 9 in parallel with step S14. At this time, it can be seen that it is more preferable that the inert gas is injected toward the space in the vicinity of the outer edge portion of the substrate 9. Further, it can be seen that it is yet more preferable that the film thickness of the low-oxygen processing liquid on the substrate 9 is kept relatively thick by setting the rotation speed of the substrate 9 in step S14 to the first rotation speed lower than the second rotation speed in step S15. The first rotation speed is preferably equal to or less than 200 rpm.

The above-described substrate processing apparatus 1 and substrate processing method may be modified in various ways.

For example, the setting of the target value of the dissolved oxygen concentration in step S11 may be omitted. In this case, a low-oxygen processing liquid having a desired dissolved oxygen concentration may be obtained, for example, by deoxidizing the processing liquid for a predetermined time in step S12. In step S12, the processing liquid may be deoxidized by various apparatuses other than the bubbling apparatus 77a and the degassing module 77b.

The supply of the inert gas to the processing space 90 (step S13) performed in parallel with step S14 may be performed without the center nozzle 73, that is, may be performed with only the plurality of side nozzles 73a. Alternatively, the supply of the inert gas may be performed without the side nozzles 73a, that is, may be performed with only the center nozzle 73. The supply of the inert gas to the processing space 90 may be omitted.

The dissolved oxygen concentration of the low-oxygen processing liquid when supplied to the substrate 9 in step S14 does not necessarily have to be equal to or less than 500 ppb, and may be greater than 500 ppb.

The rotation speed of the substrate 9 in step S14 does not necessarily have to be lower than the rotation speeds of the substrate 9 in steps S15 and S16, and may be changed as appropriate. In step S14, the substrate 9 does not necessarily have to be rotated, and a liquid film of the low-oxygen processing liquid may be formed on the substrate 9 by supplying the low-oxygen processing liquid to the upper surface 91 of the substrate 9 at rest. This makes it possible to puddle the upper surface 91 of the substrate 9 with the low-oxygen processing liquid.

The processing in step S14 does not necessarily have to be performed as a cleaning process for removing the pre-process residue from the substrate 9, and may be performed as various processes (for example, other cleaning process, etching process or the like) performed by supplying the low-oxygen processing liquid to the upper surface 91 of the substrate 9

In the aforementioned substrate processing method, for example, before step S14, or between steps S14 and S15, the substrate 9 may be processed by supplying a processing liquid other than the aforementioned processing liquid to the upper surface 91 of the substrate 9. In this case, it is preferable that the other processing liquid is also deoxidized before supply to the substrate 9. Further, the rinsing liquid supplied to the substrate 9 in step S15 may also be deoxidized before supply to the substrate 9.

The first metal part 93 of the substrate 9 processed by the above substrate processing method does not necessarily have to be included in the wiring part 96, and may be a metal part other than the wiring part 96. The same applies to the second metal part 94.

In the substrate processing apparatus 1, the top plate 5 may be located at the position shown in FIG. 1 when the low-oxygen processing liquid is supplied to the substrate 9. Further, the top plate 5 may be omitted from the substrate processing apparatus 1. The substrate processing apparatus 1 does not necessarily have to be a single wafer processing apparatus, and may be a batch-type processing apparatus that simultaneously immerses a plurality of substrates 9 in a low-oxygen processing liquid stored in a storage tank to process the plurality of substrates 9.

The substrate processing method and the substrate processing apparatus 1 described above may be used for, other than the semiconductor substrate, processing a glass substrate used for a flat panel display such as a liquid crystal display device or an organic EL (Electro Luminescence) display device, or a glass substrate used for another type of display device. The substrate processing method and the substrate processing apparatus 1 described above may be used for processing an optical disk substrate, a magnetic disk substrate, a magneto-optical disk substrate, a photomask substrate, a ceramic substrate, a solar cell substrate, and the like.

The configurations in the above-discussed preferred embodiments and variations may be combined as appropriate only if these do not conflict with one another.

While the invention has been shown and described in detail, the foregoing description is in all aspects illustrative and not restrictive. It is therefore understood that numerous modifications and variations can be devised without departing from the scope of the invention.

### REFERENCE SIGNS LIST

1 Substrate processing apparatus
9 Substrate
71 Liquid supply part
77 Oxygen reduction part
90 Processing space
91 Upper surface
93 First metal part
94 Second metal part
96 Wiring part
778 Permeable pipe
S11 to S16 Step

1. A substrate processing method, comprising:
a) generating a low-oxygen processing liquid by reducing oxygen dissolved in a processing liquid; and
b) processing a main surface of a substrate by supplying said low-oxygen processing liquid to said substrate, said main surface having a first metal part and a second metal part in contact with said first metal part, wherein
in said operation b), said low-oxygen processing liquid is brought into contact with an interface between said first metal part and said second metal part to inhibit oxygen reduction reaction on said second metal part which is nobler than said first metal part, and thereby to inhibit dissolution of said first metal part.

2. The substrate processing method according to claim 1, wherein
in said operation a), bubbles of a gas other than oxygen are supplied into said processing liquid to reduce oxygen in said processing liquid.

3. The substrate processing method according to claim 1, wherein
in said operation a), said processing liquid is run through a pipe made of an oxygen permeable material while a space outside said pipe is set to a low-oxygen atmosphere, to reduce oxygen in said processing liquid.

4. The substrate processing method according to claim 1, wherein
a dissolved oxygen concentration of said low-oxygen processing liquid is equal to or less than 500 ppb.

5. The substrate processing method according to claim 1, further comprising
c) setting a target value of dissolved oxygen concentration of said low-oxygen processing liquid before said operation a), wherein
in generation of said low-oxygen processing liquid in said operation a), the dissolved oxygen concentration of said low-oxygen processing liquid is controlled to be equal to or less than said target value.

6. The substrate processing method according to claim 5, wherein
in said operation c), said target value of dissolved oxygen concentration is set on the basis of a combination of said first metal part and said second metal part.

7. The substrate processing method according to claim 5, wherein
in said operation b), the dissolved oxygen concentration of said low-oxygen processing liquid when supplied to said substrate is equal to or less than said target value.

8. The substrate processing method according to claim 1, further comprising
d) supplying an inert gas into a space on said main surface of said substrate to reduce an oxygen concentration in a surrounding atmosphere, in parallel with said operation b).

9. The substrate processing method according to claim 8, wherein
in said operation d), said inert gas is injected toward a space in a vicinity of an outer edge portion of said substrate.

10. The substrate processing method according to claim 1, wherein
said low-oxygen processing liquid supplied to said substrate in said operation b) is a cleaning chemical liquid used for cleaning said main surface of said substrate,
said substrate processing method further comprises
e) rinsing said main surface of said substrate by supplying a rinsing liquid to said main surface after said operation b),
in said operation b), said low-oxygen processing liquid is supplied to said main surface of said substrate rotating at a first rotation speed, and
in said operation e), said rinsing liquid is supplied to said main surface of said substrate rotating at a second rotation speed which is higher than said first rotation speed.

11. The substrate processing method according to claim 1, wherein
said first metal part is included in a wiring part provided on said main surface of said substrate.

12. The substrate processing method according to claim 1, wherein
said processing in said operation b) is performed as a cleaning process for removing from said main surface of said substrate process residue generated in a pre-process performed before said operation b).

13. A substrate processing apparatus, comprising:
an oxygen reduction part for generating a low-oxygen processing liquid by reducing oxygen dissolved in a processing liquid; and
a liquid supply part for supplying said low-oxygen processing liquid to a substrate whose main surface has a first metal part and a second metal part in contact with said first metal part, wherein
said low-oxygen processing liquid is brought into contact with an interface between said first metal part and said second metal part to inhibit oxygen reduction reaction on said second metal part which is nobler than said first metal part, and thereby to inhibit dissolution of said first metal part.
